(19) United States
(12) Patent Application Publication
(10) Pub. No.: US 2026/0324158 A1
(43) Pub. Date: Oct. 15, 2026

(54) DISPLAY DEVICE

(71) Applicant: Innolux Corporation, Miaoli County (TW)

(72) Inventor: Shuhei Hosaka, Miaoli County (TW)

(73) Assignee: Innolux Corporation, Miaoli County (TW)

(21) Appl. No.: 19/444,199

(22) Filed: Jan. 9, 2026

Related U.S. Application Data
(60) Provisional application No. 63/785,644, filed on Apr. 9, 2025.

(51) Int. Cl. H10H 29/49

(52) U.S. Cl. CPC H10H 29/49

(57) ABSTRACT

The present disclosure provides a display device including a first pixel group including a first pixel and a second pixel arranged along a first direction, a second pixel group including a third pixel and a fourth pixel arranged along the first direction, a signal line electrically connected to at least one of the first pixel, the second pixel, the third pixel, and the fourth pixel, a first power line for receiving a first voltage, a second power line for receiving a second voltage different from the first voltage, and an electrostatic protection circuit disposed between the first pixel group and the second pixel group and including a first circuit electrically connected to the signal line and the first power line and a second circuit electrically connected to the signal line and the second power line, wherein the first and second circuits are located between the first and second power lines.

### CROSS-REFERENCE TO RELATED APPLICATION

This application claims the priority benefit of U.S. provisional application serial no. 63/785,644, filed on Apr. 9, 2025. The entirety of the above-mentioned patent application is hereby incorporated by reference herein and made a part of this specification.

### BACKGROUND

### Technical Field

The present disclosure relates to an electronic device, and particularly relates to a display device.

### Description of Related Art

With the continuous progress of the technology industry, display devices have been extensively adopted in various products such as televisions, computers, and mobile phones. Recently, narrow-bezel displays have become a prevailing trend in the development of high-quality display devices due to their advantages of simplified appearance, enhanced aesthetics, and an increased display area in a given panel size. However, the arrangement of various components disposed in the display region is constrained by the limited space. Accordingly, there is a continuous need for further improvements in integrating certain components, which were originally arranged in the peripheral region, into the display region so as to satisfy current or future needs.

### SUMMARY

The present disclosure provides a display device in which an electrostatic protection circuit is arranged in an active region of the display device, which is beneficial to increasing the horizontal area of the active region, and thereby providing advantages to the borderless design.

According to an embodiment of the present disclosure, the display device includes a first pixel group including a first pixel and a second pixel arranged along a first direction, a second pixel group including a third pixel and a fourth pixel arranged along the first direction, a signal line electrically connected to at least one of the first pixel, the second pixel, the third pixel, and the fourth pixel, a first power line for receiving a first voltage, a second power line for receiving a second voltage different from the first voltage, and an electrostatic protection circuit disposed between the first pixel group and the second pixel group, and including a first circuit and a second circuit. The first circuit is electrically connected to the signal line and the first power line, and the second circuit is electrically connected to the signal line and the second power line, wherein the first circuit and the second circuit are located between the first power line and the second power line.

Based on the above, in the display device of the present disclosure in accordance with the embodiment, the electrostatic protection circuit is designed to be disposed between the first pixel group and the second pixel group, which is beneficial to increasing the horizontal area of the active region, and thereby providing advantages to the borderless design.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view illustrating a display device according to an embodiment of the present disclosure.

FIGS. 2, 3, and 4 are schematic top views illustrating display devices according to various embodiments of the present disclosure.

FIG. 5 is a schematic top view illustrating a display device before cutting according to an embodiment of the present disclosure.

FIG. 6 is a schematic top view illustrating a display device after cutting according to an embodiment of the present disclosure.

FIG. 7 is a schematic circuit diagram showing an electrostatic protection circuit according to an embodiment of the present disclosure.

FIG. 8 is a schematic top view showing a portion of a display device according to an embodiment of the present disclosure.

FIG. 9 is a schematic top view showing a portion of peripheral region of a display device according to an embodiment of the present disclosure.

### DESCRIPTION OF THE EMBODIMENTS

The disclosure can be understood with reference to the following detailed description in conjunction with the accompanying drawings. It should be noted that, for ease of understanding by readers and for the concision of the illustration, a plurality of drawings in the disclosure only depict parts of the electronic device or the transistor, and certain elements in the drawings are not drawn according to the actual scale. In addition, the number and size of each element in the drawings are for illustration only, and are not intended to limit the scope of the disclosure. For example, the relative sizes, thicknesses and positions of various layers, regions and/or structures may be reduced or enlarged for clarity.

Certain terms may be used throughout the disclosure and the claims to refer to specific elements. Those skilled in the art will understand that electronic device manufacturers may refer to the same elements by different names. The disclosure does not intend to distinguish between elements that have the same function but have different names. In the following description and claims, the words such as “having”, “comprising” and “including” are open-ended words, and thus should be interpreted as the meaning of “including but not limited to.”

In this document, "one component is disposed on another component" is for convenience in describing the relative position between the said component and the said another component, and is not intended to limit the process steps or sequence between the said component and the said another component.

Directional terms mentioned herein, such as “up,” “down,” “front,” “rear,” “left,” “right,” and the like refer only to the directions of the drawings. Accordingly, the directional terms are used for illustration, and are not intended to limit the disclosure. It should be understood that when an element or a film layer is referred to as being “disposed on” or “connected to” another element or film layer, the element or the film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. In addition, when the element or film layer is referred to as overlapping with another element, the element or film layer at least partially overlaps with another element or film layer. The terms related to bonding and connection may also include the case where both structures are movable, or both structures are fixed. Furthermore, the terms “electrically connected” or “coupled” includes any direct and indirect means of electrical connection.

In the text, the terms “substantially” usually implies that a value is within 10% of a given value or range, or within 5%, 3%, 2%, 1%, or 0.5% of a given value or range. In addition, the description “a given range from a first value to a second value” or “a given range between a first value and a second value” implies that the given range includes the first value, the second value, and other values in between.

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

The exemplary embodiments of this disclosure are described in the following for example, and the same reference numerals used in the figures and descriptions are represented to the same or similar portions.

The display device may be a rollable display device, a flexible display device, or a display tiled device, but the present disclosure is not limited thereto. The display device may include a non-self-luminous panel such as a liquid crystal panel or other self-luminous panels, but the present disclosure is not limited thereto.

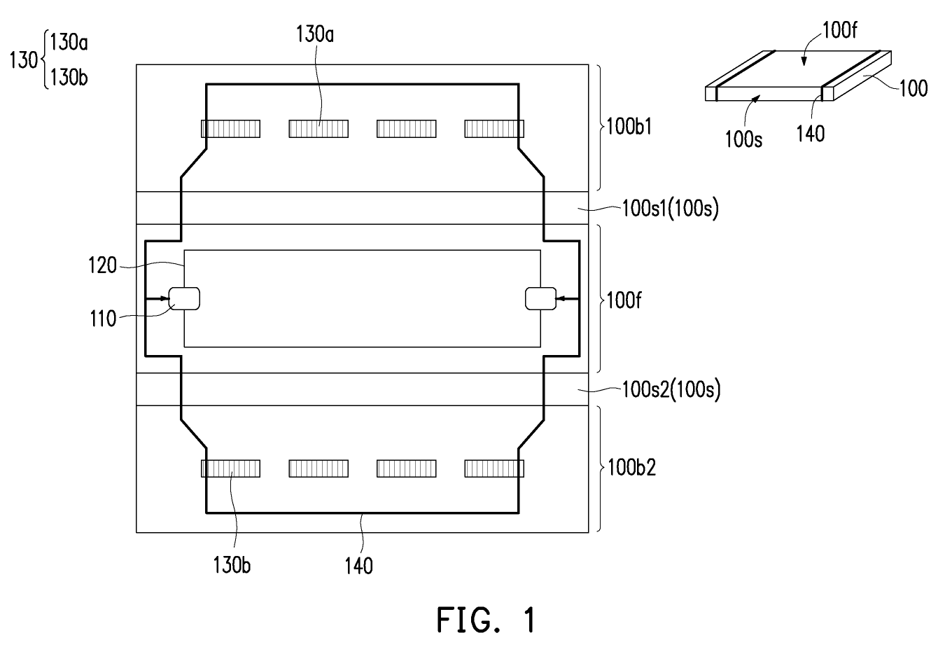

FIG. 1 is a schematic view illustrating a display device according to an embodiment of the present disclosure. Referring to FIG. 1, a display device including a substrate 100 is provided. The substrate 100 may include a rigid material or a flexible material. The substrate 100 may be made of transparent materials such as glass. The substrate 100 may be an array substrate where a device layer including active devices, passive devices, and conductive wirings is formed thereon. The active devices may include switching components such as transistors (e.g., thin film transistors (TFTs)) and light-emitting components such as a light emitting diode (LED), a quantum dot (QD), a fluorescence, a phosphor, other suitable materials, or combinations thereof. The passive devices may include capacitors, resistors, inductors, or combinations thereof. The light emitting diode may include, for example, an organic light emitting diode (OLED), a mini-LED, a micro-LED, or a quantum dot light emitting diode (QLED, QDLED), but is not limited thereto. The conductive wirings may include signal lines such as data lines, scan lines, or combinations thereof. In the illustrated embodiment as shown in FIG. 1, the substrate 100 includes a front surface 100f where the device layer is disposed thereon, a rear surface including a first rear region 100b1 and a second rear region 100b2, a first side surface 100s1 connecting the first rear region 100b1 to the front surface 100f, and a second side surface 100s2 connecting the second rear region 100b2 to the front surface 100f.

Referring to FIG. 1, the display device may be a borderless display device, that is, an active region where the device layer is disposed thereon may have a horizontal area substantially equal to or slightly smaller than that of the front surface 100f. In this case, integrated circuits (ICs) such as driver ICs or data ICs, and/or other functional circuits such as inspection circuits that were originally configured in the peripheral region surrounding the active region are configured on the rear surface of the substrate 100. For example, the rear surface of the substrate 100 is bonded to a chip-on-film (COF), wherein first pads 130a and second pads 130b are configured in the first rear region 100b1 and the second rear region 100b2 for electrical connections. In certain embodiments, the first pads 130a may be referred to as flexible printed circuit (FPC) pads, and the second pads 130b may be referred to as COF pads, but the present disclosure is not limited thereto.

In the illustrated embodiment shown in FIG. 1, the display device includes electrostatic protection circuits 110 configured in the active region in the front surface 100f of the substrate 100, which is beneficial to increasing the horizontal area of the active region, and thereby providing advantages to the borderless design. The electrostatic protection circuits 110 may be electrically connected through a wiring 120 configured in the active region in the front surface 100f of the substrate 100. The wiring 120 may include any suitable conductive material, such as copper (Cu), aluminum (Al), nickel (Ni), molybdenum (Mo), titanium (Ti), alloys or combinations of the above materials, or other suitable materials, but the present disclosure is not limited thereto. Referring to FIG. 1, the display device may further include a guard ring 140 surrounding the active region and extending from the front surface 100f to the first rear region 100b1 and the second rear region 100b2 of the rear surface. In some embodiments, the guard ring 140 may include portions disposed on the first side surface 100s1 and the second side surface 100s2. In some embodiments, the guard ring 140 may be electrically floating or may be connected to the ground (GND).

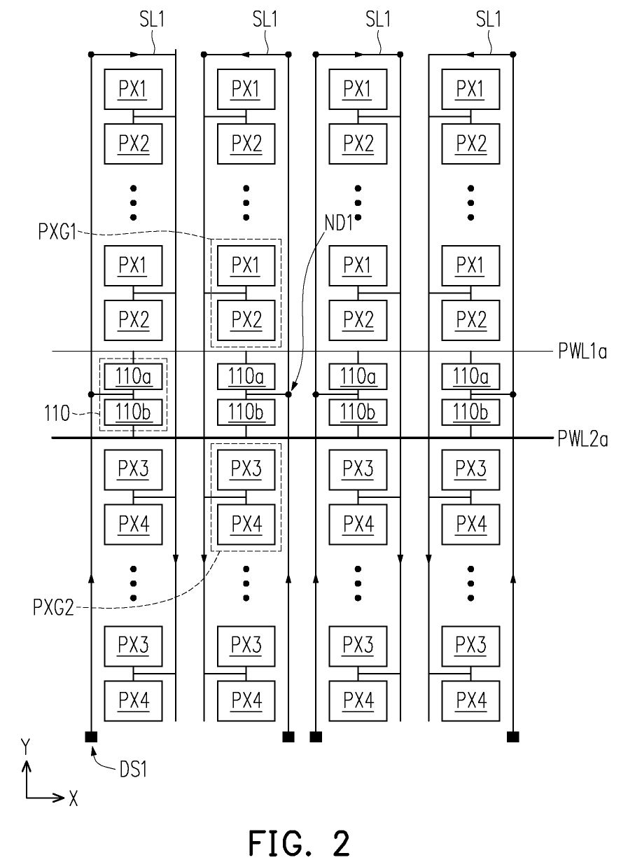

FIGS. 2, 3, and 4 are schematic top views illustrating display devices according to various embodiments of the present disclosure. Layouts as illustrated in FIGS. 2-4 are provided to integrate the electrostatic protection circuits 110 into the active region of the display device.

Referring to FIGS. 2-4, the display device includes a first pixel group PXG1 including a first pixel PX1 and a second pixel PX2 arranged along the first direction (e.g., Y direction), a second pixel group PXG2 including a third pixel PX3 and a fourth pixel PX4 arranged along the first direction, a signal line SL1 connected to at least one of the first pixel PX1, the second pixel PX2, the third pixel PX3, and the fourth pixel PX4, a first power line PWL1a (or PWL1b) for receiving a first voltage (e.g., VGL), a second power line PWL2a (or PWL2b) for receiving a second voltage (e.g., VGH) different from the first voltage, and an electrostatic protection circuit 110 disposed between the first pixel group PXG1 and the second pixel group PXG2. In some embodiments, the first voltage may be a gate low voltage (i.e., VGL), and the second voltage may be a gate high voltage (i.e., VGH). In some embodiments, the first power line PWL1a (or PWL1b) and the second power line PWL2a (or PWL2b) may be included in the wiring 120 shown in FIG. 1.

In the illustrated embodiments as shown in FIGS. 2-4, the first pixel group PXG1 and the second pixel groups PXG2 are provided in plural and arranged in an array form. In some embodiments, each of the first pixel PX1, the second pixel PX2, the third pixel PX3, and the fourth pixel PX4 may include switching components such as transistors (e.g., thin film transistors (TFTs)) and light-emitting components such as a light emitting diode (LED), but is not limited thereto.

In the illustrated embodiments as shown in FIGS. 2-4, the electrostatic protection circuit 110 is provided in plural and arranged along the second direction (e.g., X direction) different from the first direction (e.g., Y direction), but is not limited thereto. For example, the electrostatic protection circuits 110 may be arranged in an array form in some other embodiments. In the illustrated embodiments, each of the electrostatic protection circuits 110 includes a first circuit 110a and a second circuit 110b located between the first power line PWL1a (or PWL1b) and the second power line PWL2a (or PWL2b) in which the first circuit 110a is electrically connected to the signal line SL1 (or SL2) and the first power line PWL1a (or PWL1b), and the second circuit 110b is electrically connected to the signal line SL1 (or SL2) and the second power line PWL2a (or PWL2b).

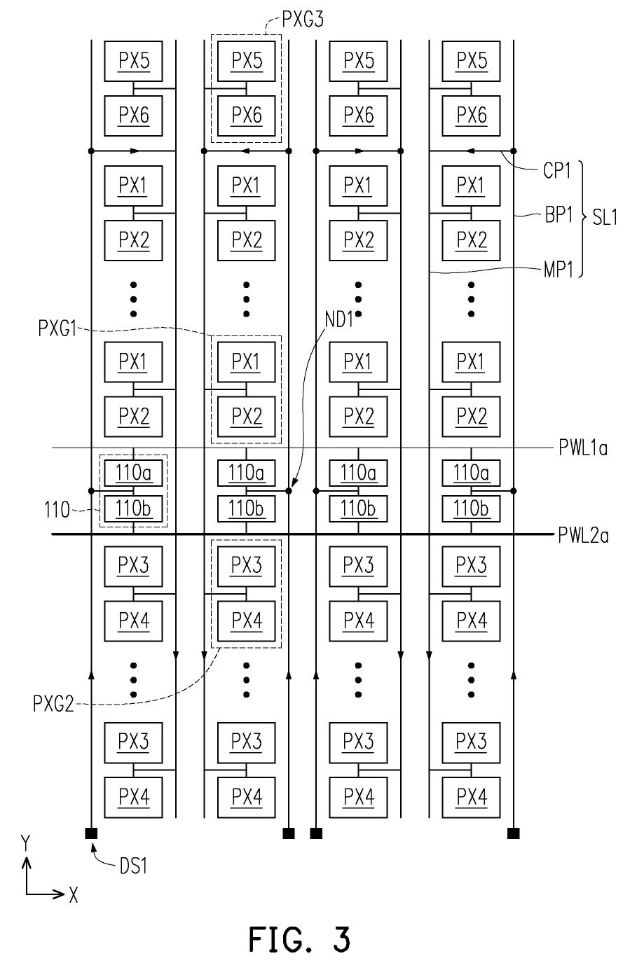

In the illustrated embodiments as shown in FIGS. 2 and 3, the signal line SL1 may be a data line. At least a portion of the signal line SL1 extends along the first direction (e.g., Y direction), and is electrically connected to the first pixel PX1, the second pixel PX2, the third pixel PX3, and the fourth pixel PX4. The signal line SL1 may be provided in plural and arranged long the second direction (e.g., X direction), but the present disclosure is not limited thereto.

In the illustrated embodiments as shown in FIGS. 2 and 3, the signal line SL1 includes a main portion MP1, a branch portion BP1, and a connection portion CP1 connecting the main portion MP1 and the branch portion BP1, and the first pixel groups PXG1 and the second pixel group PXG2 are disposed between the main portion MP1 and the branch portion BP1. In this embodiment, the main portion MP1 may be connected to and transmit data signal to the first pixel PX1, the second pixel PX2, the third pixel PX3, and the fourth pixel PX4. The branch portion BP1 is configured to receive a data signal transmitted from an edge of the display device (e.g., the data signal DS1 transmitted from the edge region of the display device), and the data signal is transmitted to the main portion MP1 through the connection portion CP1. The electrostatic protection circuit 110 is coupled to a node ND1 of the branch portion BP1, so as to enhance the protection for the switching components included in the pixels (e.g., first to fourth pixels PX1-PX4) and/or the data IC, and to reduce interference/noise couped into the pixels (e.g., first to fourth pixels PX1-PX4). In some embodiments, the node ND1 may be located between the first power line PWL1a and the second power line PWL2a. In the illustrated embodiments as shown in FIGS. 2 and 3, the main portion MP1 and the branch portion BP1 extend along the first direction (e.g., Y direction) and are separated from each other in the second direction (X direction) crossing the first direction, and the connection portion CP1 extends along the second direction.

In some other embodiments, referring to FIG. 3, the display device further includes a third pixel group PXG3, wherein the connection portion CP1 is disposed between the third pixel group PXG3 and the first pixel group PXG1. In some embodiments, the third pixel group PXG3 may include a fifth pixel PX5 and a sixth pixel PX6 arranged along the first direction (e.g., Y direction), and each of the fifth pixel PX5 and the sixth pixel PX6 may include the switching components and the light-emitting components as described above.

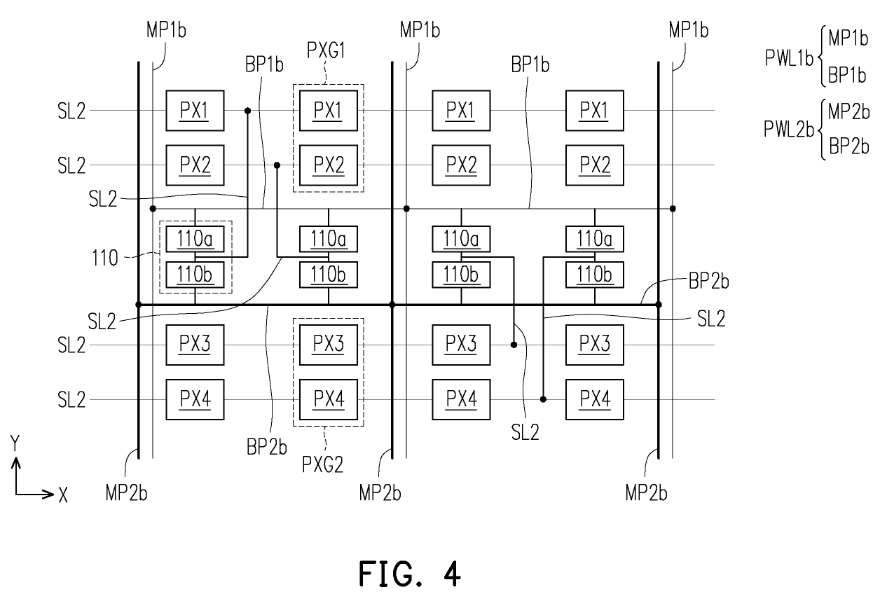

In the illustrated embodiments as shown in FIG. 4, the signal line SL2 may be a scan line extending along the second direction (e.g., X direction) crossing the first direction (e.g., Y direction), and is electrically connected to one of the first pixel PX1, the second pixel PX2, the third pixel PX3, and the fourth pixel PX4. In some embodiments, the second direction may be perpendicular to the first direction, but the present disclosure is not limited thereto. In some embodiments, the signal line SL2 may be provided in plural and arranged long the first direction (e.g., Y direction), but the present disclosure is not limited thereto.

In the illustrated embodiment as shown in FIG. 4, the first power line PWL1b includes a plurality of first main portions MP1b extending along the first direction (e.g., Y direction) and a plurality of first branch portion BP1b extending along the second direction (e.g., X direction). In some embodiments, the first pixel group PXG1 and the second pixel group PXG2 may be located between two adjacent ones of the plurality of first main portions MP1b. In the illustrated embodiment as shown in FIG. 4, the second power line PWL2b includes a plurality of second main portions MP2b extending along the first direction (e.g., Y direction) and a plurality of second branch portion BP2b extending along the second direction (e.g., X direction). In some embodiments, the first circuit 110a and the second circuit 110b may be located between the first branch portion BP1b and the second branch portion BP2b. In some embodiments, the first branch portion BP1b and the second branch portion BP2b may be located between the first pixel group PXG1 and the second pixel group PXG2.

In the illustrated embodiment as shown in FIG. 4, the electrostatic protection circuit 110 is coupled to the scan line (e.g., signal line SL2) electrically connected to the pixel (e.g., the first pixel PX1, the second pixel PX2, the third pixel PX3, or the fourth pixel PX4), so as to enhance the protection for the switching components included in the pixels and/or the gate driver IC and to reduce the issues such as flicker or line mura that are caused by the gate line noise.

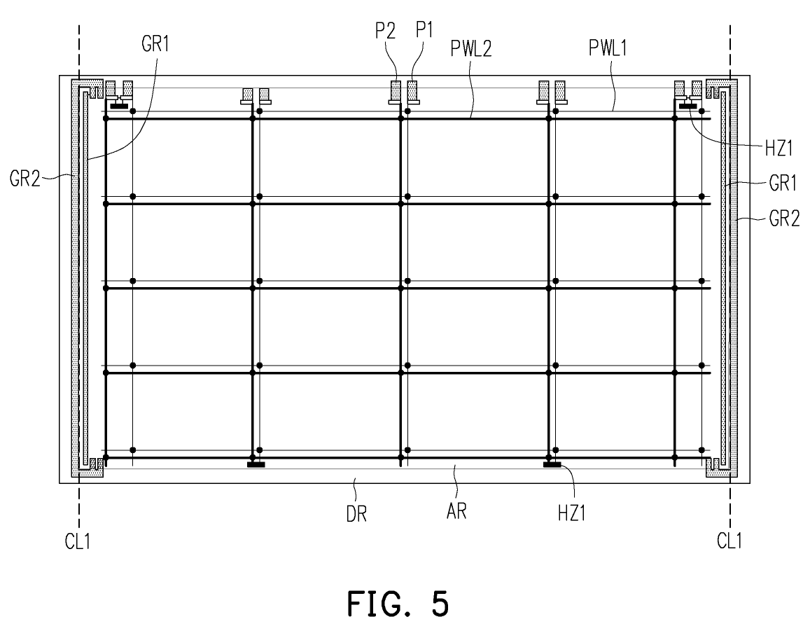

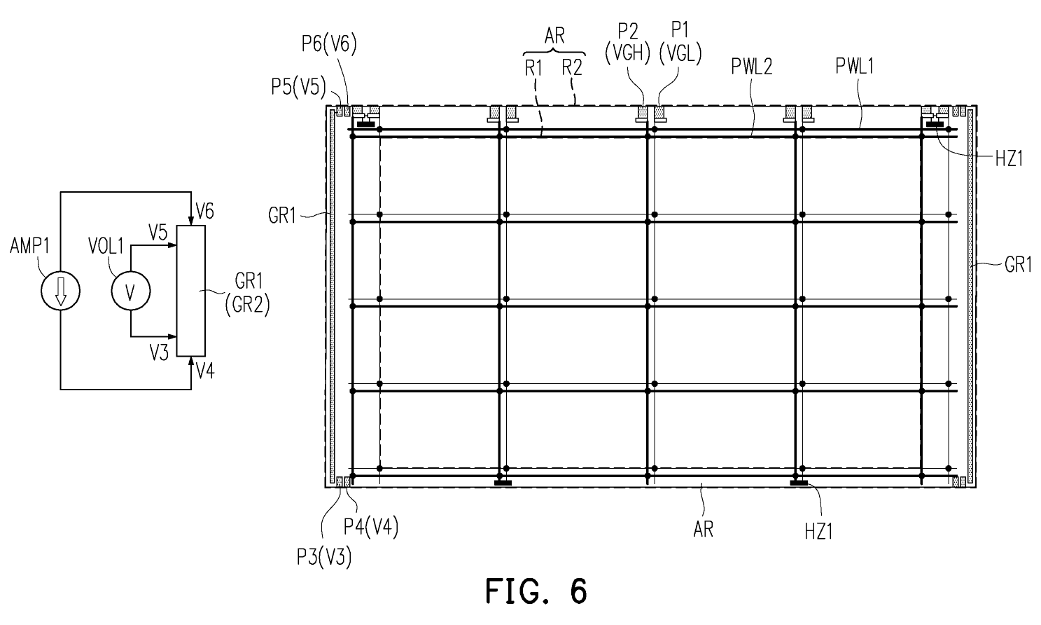

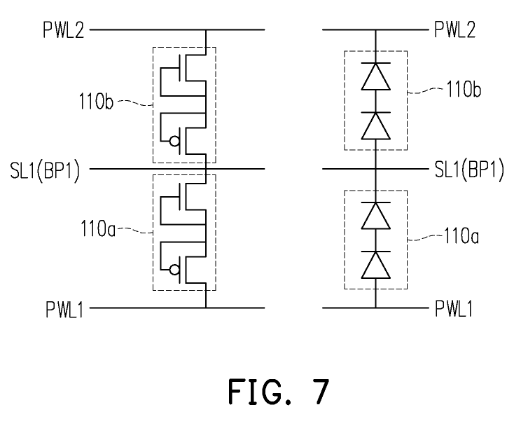

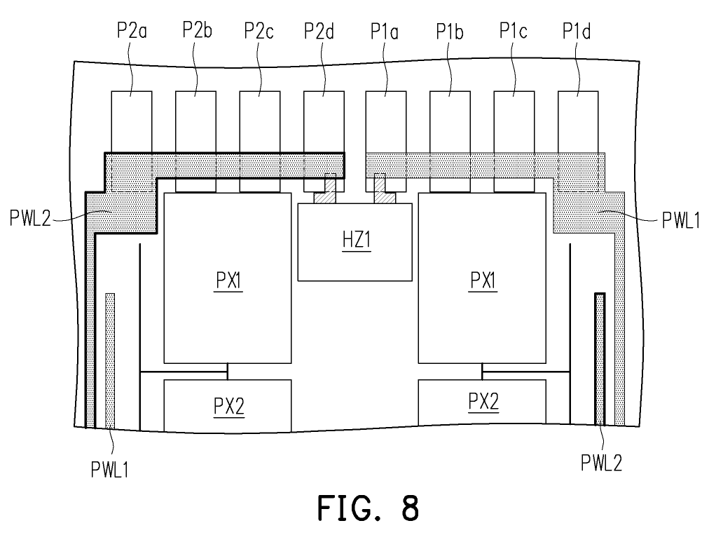

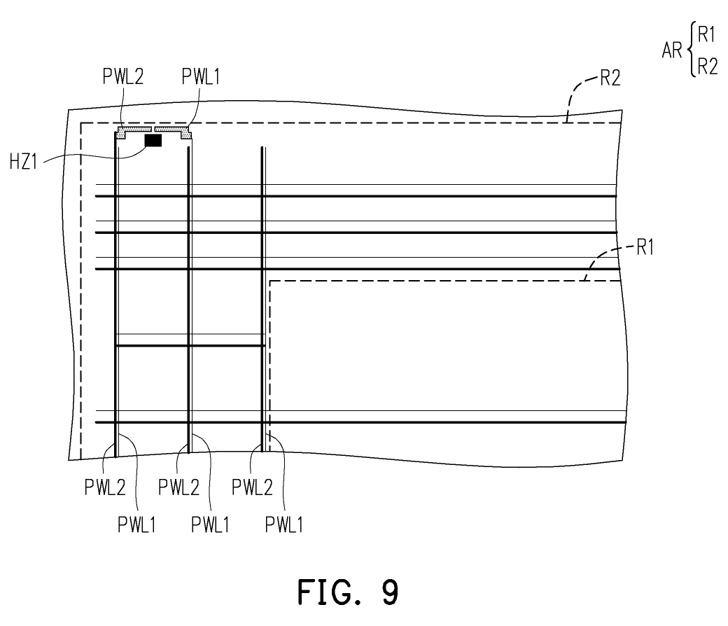

FIG. 5 is a schematic top view illustrating a display device before cutting according to an embodiment of the present disclosure. FIG. 6 is a schematic top view illustrating a display device after cutting according to an embodiment of the present disclosure. FIG. 7 is a schematic circuit diagram showing an electrostatic protection circuit according to an embodiment of the present disclosure. FIG. 8 is a schematic top view showing a portion of a display device according to an embodiment of the present disclosure. FIG. 9 is a schematic top view showing a portion of peripheral region of a display device according to an embodiment of the present disclosure.

In the illustrated embodiments as shown in FIGS. 5 and 6, the display device further includes a resistive component HZ1 electrically connected to the first power line PWL1 and the second power line PWL2. The resistive component HZ1 can be configured to provide a short circuit between first power line PWL1 and second power line PWL2 for electrostatic discharge (ESD) protection during fabrication. Alternatively, it can be severed to create an open circuit, thereby enabling accurate and independent voltage control for high-fidelity display operation. In some embodiments, the resistive component HZ1 may be disposed in a peripheral region of the display device. In the illustrated embodiments as shown in FIGS. 5 and 6, the active region AR may include a pixel region R1 where the pixels are arranged therein and a peripheral region R2 surrounding the pixel region R1. Referring to FIG. 6, the resistive component HZ1 is disposed in the peripheral region R2 of the display device. In some embodiments, the resistive component HZ1 may be electrically connected to the guard ring (e.g., the guard ring 140 shown in FIG. 1, the inner guard ring GR1 and the outer guard ring GR2 shown in FIG. 5, or the inner guard ring GR1 shown in FIG. 6).

Referring to FIG. 5, the display device may include an inner guard ring GR1 and an outer guard ring GR2 before the display device is cut along the cutting lines CL1. In this embodiment, the display device includes the active region AR and the dummy region DR around the active region AR, wherein the inner guard ring GR1 is disposed in the active region AR and positioned inside the cutting lines CL1, and the outer guard ring GR2 is disposed in the dummy region DR and positioned outside the cutting lines CL1. In some embodiments, the display device may include a first feature P1 connecting to the first power line PWL1 and a second feature P2 connecting to the second power line PWL2. In some embodiments, the first feature P1 and the second feature P2 may be test features (e.g., test pads) for measuring the electrical characteristics of the first power line PWL1 and the second power line PWL2, but the present disclosure is not limited thereto. In some other embodiments, the first feature P1 and the second feature P2 may be connection features (e.g., connection pads) for transmitting the first voltage (e.g., VGL) and the second voltage (e.g., VGH) to the first power line PWL1 and the second power line PWL2, respectively. In some alternative embodiments, the first feature P1 and the second feature P2 may be power features (e.g., connection pads) for providing the first voltage (e.g., VGL) and the second voltage (e.g., VGH). In some embodiments, the first feature P1 may be configured in plural (e.g., the first features P1a, P1b, P1c and P1d shown in FIG. 8), and the second features may be configured in plural (e.g., the second features P2a, P2b, P2c and P2d shown in FIG. 8).

Referring to FIGS. 5 and 6, a cutting process is performed on the display device so that the display device is cut along the cutting lines CL1, and the outer guard ring GR2 is removed accordingly. In some embodiments, the cutting process includes a grinding process, but the present disclosure is not limited thereto. In some embodiments, the display device may further include a third feature P3, a fourth feature P4, a fifth feature P5, and a sixth feature P6 for monitoring the cutting process. For example, the third feature P3 and the fifth feature P5 may be the test pads respectively connecting to two opposite ends of the voltmeter VOL1 and two opposite ends of the inner and outer guard rings GR1 and GR2 (e.g., V3 and V5 shown in FIG. 6); and the fourth feature P4 and the sixth feature P6 may be test pads respectively connecting to two opposite ends of the power supply AMP1 (e.g., current source) and two opposite ends of the inner and outer guard rings GR1 and GR2 (e.g., V4 and V6 shown in FIG. 6). Accordingly, the resistance of the inner and outer guard rings GR1 and GR2 can be monitored during the cutting process. In some embodiments, when the measured resistance reaches a predetermined value, that is, when the resistance remains stable during the cutting process, it may indicate that the cutting process has been completed.

In some embodiments, the first power line PWL1 and the second power line PWL 2 may be respectively configured in mesh patterns (as shown in FIG. 6) to accelerate the electrostatic discharge. In some other embodiments, the first power line PWL1 and the second power line PWL 2 may be respectively configured in mesh patterns in the peripheral region R2 (as shown in FIG. 9) to further accelerate the electrostatic discharge.

In the illustrated embodiment as shown in FIG. 7, each of the first circuit 100a and the second circuit 100b includes a plurality of diodes that are connected in series with one another. In some embodiments, each of the first circuit 100a and the second circuit 100b may include a plurality of TFTs that are connected in series with one another to realize the diodes connected in series with one another. Referring to FIG. 7, one end of the first circuit 100a or the second circuit 100b is connected to the data signal transmitted from the edge of the display device (e.g., the branch portion BP1 of the signal line SL1); another end of the first circuit 100a is connected to the first power line PWL1; and another end of the second circuit 100b is connected to the second power line PWL2.

In summary, in the display device described in the above embodiments, the electrostatic protection circuit is designed to be disposed between the first pixel group and the second pixel group, which is beneficial to increasing the horizontal area of the active region, and thereby providing advantages to the borderless design.

The above embodiments are used to describe the technical solution of the disclosure and are not a limitation thereof. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

Although the embodiments of the disclosure and their advantages are disclosed as above, it should be understood that any person with ordinary skill in the art, without departing from the spirit and scope of the disclosure, may make changes, substitutions, and modifications, and features between the embodiments may be mixed and replaced at will to form other new embodiments. In addition, the scope of the disclosure is not limited to the manufacturing processes, machines, manufactures, material compositions, devices, methods, and steps in the specific embodiments described in the specification. Any person with ordinary skill in the art may understand the current or future development processes, machines, manufactures, material compositions, devices, methods, and steps from the content of the disclosure, which may all be adopted according to the disclosure as long as they may implement substantially the same function or obtain substantially the same result in an embodiment described here. Therefore, the scope of the disclosure includes the above manufacturing processes, machines, manufactures, material compositions, devices, methods, and steps. In addition, each claim constitutes an individual embodiment, and the scope of the disclosure also includes the combination of each claim and embodiment. The scope of the disclosure shall be subject to the scope defined by the following claims.

What is claimed is:

1. A display device, comprising:
a first pixel group comprising a first pixel and a second pixel arranged along a first direction;
a second pixel group comprising a third pixel and a fourth pixel arranged along the first direction;
a signal line electrically connected to at least one of the first pixel, the second pixel, the third pixel, and the fourth pixel;
a first power line for receiving a first voltage;
a second power line for receiving a second voltage different from the first voltage; and
an electrostatic protection circuit disposed between the first pixel group and the second pixel group and comprising:
a first circuit electrically connected to the signal line and the first power line; and
a second circuit electrically connected to the signal line and the second power line,
wherein the first circuit and the second circuit are located between the first power line and the second power line.

2. The display device of claim 1, wherein the signal line is a data line extending along the first direction.

3. The display device of claim 2, wherein the signal line is electrically connected to the first pixel, the second pixel, the third pixel, and the fourth pixel.

4. The display device of claim 2, wherein the signal line comprises a main portion, a branch portion, and a connection portion connecting the main portion and the branch portion, and the first pixel group and the second pixel group are disposed between the main portion and the branch portion.

5. The display device of claim 4, wherein the electrostatic protection circuit is coupled to a node of the branch portion.

6. The display device of claim 5, wherein the node is located between the first power line and the second power line.

7. The display device of claim 4, wherein the branch portion is configured to receive a data signal transmitted from an edge of the display device, and the data signal is transmitted to the main portion through the connection portion.

8. The display device of claim 4, wherein the main portion and the branch portion extend along the first direction and are separated from each other in a second direction crossing the first direction, and the connection portion extends along the second direction.

9. The display device of claim 4, further comprising:
a third pixel group, wherein the connection portion is disposed between the third pixel group and the first pixel group.

10. The display device of claim 1, wherein the signal line is a scan line extending along a second direction crossing the first direction.

11. The display device of claim 10, wherein the signal line is electrically connected to one of the first pixel, the second pixel, the third pixel, and the fourth pixel.

12. The display device of claim 10, wherein the first power line comprises a plurality of first main portions extending along the first direction and a plurality of first branch portion extending along the second direction.

13. The display device of claim 12, wherein the first pixel group and the second pixel group are located between two adjacent ones of the plurality of first main portions.

14. The display device of claim 12, wherein the second power line comprises a plurality of second main portions extending along the first direction and a plurality of second branch portion extending along the second direction.

15. The display device of claim 14, wherein the first circuit and the second circuit are located between the first branch portion and the second branch portion.

16. The display device of claim 15, wherein the first branch portion and the second branch portion are located between the first pixel group and the second pixel group.

17. The display device of claim 1, further comprising:
a resistive component electrically connected to the first power line and the second power line.

18. The display device of claim 17, wherein the resistive component is disposed in a peripheral region of the display device.

19. The display device of claim 1, wherein the first power line and the second power line are configured in mesh patterns, respectively.

20. The display device of claim 1, wherein each of the first circuit and the second circuit comprises a plurality of diodes that are connected in series with one another.
